(19) United States
(12) Patent Application Publication
(10) Pub. No.: US 2021/0057456 A1
(43) Pub. Date: Feb. 25, 2021

(54) ARRAY SUBSTRATE, MANUFACTURING METHOD THEREOF, AND DISPLAY DEVICE

(71) Applicant: SHENZHEN ROYOLE TECHNOLOGIES CO., LTD., Shenzhen (CN)

(72) Inventors: Guowen YAN, Shenzhen (CN); Zhiyuan LIN, Shenzhen (CN); Chuni LIN, Shenzhen (CN); Qihua ZHOU, Shenzhen (CN)

(21) Appl. No.: 17/092,573

(22) Filed: Nov. 9, 2020

Related U.S. Application Data
(63) Continuation of application No. PCT/CN2018/086124, filed on May 9, 2018.

(51) Int. Cl. H01L 27/12

(52) U.S. Cl. CPC H01L 27/1225; H01L 27/1259; H01L 27/1248

(57) ABSTRACT

An array substrate, a manufacturing method for the array substrate, and the display device are provided. The array substrate includes a substrate. The substrate includes at least one first region and at least one second region. A low temperature poly-silicon thin film transistor is disposed in the at least one first region, and an oxide thin film transistor is disposed in the at least one second region. The oxide-TFT includes an oxide semiconductor layer, a gate insulation layer, a gate electrode, a source electrode, and a drain electrode. The oxide semiconductor layer includes a channel portion and contact portions connected to the channel portion. The channel portion, the gate insulation layer, and the gate electrode are sequentially stacked. The contact portions are respectively in contact with the source electrode and the drain electrode, and the channel portion at least partially protrudes in a direction away from the substrate.

### CROSS-REFERENCE TO RELATED APPLICATION(S)

This application is a continuation of International Application No. PCT/CN2018/086124, filed on May 9, 2018, the entire disclosure of which is hereby incorporated by reference in its entirety.

### TECHNICAL FIELD

This disclosure relates to the technical field of display, and particularly to an array substrate, a manufacturing method thereof, and a display device.

### BACKGROUND

The low temperature polycrystalline oxide (LTPO) technology combines advantages of two types of thin film transistors, i.e., low temperature poly-silicon thin film transistors (LTPS-TFTs) and oxide thin film transistors (Oxide-TFTs). The LTPO has advantages of high pixels per inch (PPI), low power consumption, high image quality, and the like. Generally, the output TFTs use LTPS with high mobility to improve the luminous brightness while the switch TFTs use oxide-TFTs (such as indium gallium zinc oxide (IGZO)) with low off-state current to reduce power consumption thereof. However, in the oxide-TFT, there is a small amount of carriers (e.g. about 1 micron (1 μm)) which may diffuse from a conductive region to a semiconductor region. To this end, it is necessary to reserve enough length for the channel of the amorphous oxide-TFT, which affects the improvement of resolution, thereby affecting display quality.

### SUMMARY

In view of the above, implementations of the disclosure provide an array substrate, a manufacturing method thereof, and a display device.

An array substrate is provided. The array substrate includes a substrate. The substrate includes at least one first region and at least one second region. A low temperature poly-silicon thin film transistor (LTPS-TFT) is disposed in the at least one first region, and an oxide thin film transistor (oxide-TFT) is disposed in the at least one second region, where the oxide-TFT includes an oxide semiconductor layer, a gate insulation layer, a gate electrode, a source electrode, and a drain electrode. The oxide semiconductor layer includes a channel portion and contact portions connected to the channel portion. The channel portion, the gate insulation layer, and the gate electrode are sequentially stacked, the contact portions are respectively in contact with the source electrode and the drain electrode, and the channel portion at least partially protrudes in a direction away from the substrate.

In at least one implementation, the channel portion includes a first part and two second parts respectively disposed at two opposite ends of the first part, where each of the two second parts is bent toward the substrate from one of the two opposite ends of the first part.

In at least one implementation, the first part is parallel to the substrate, and an angle defined between each of the two second parts and the first part is larger than 90 degrees and smaller than 180 degrees.

In at least one implementation, the channel portion further includes two third parts, where each of the two third parts is connected between one of the two second parts and one of the contact portions.

In at least one implementation, the two third parts are both parallel to the first part.

In at least one implementation, the oxide-TFT further includes a support portion, where the support portion protrudes relative to the at least one second region of the substrate, and the channel portion is at least partially disposed on the support portion.

In at least one implementation, the support portion includes a first support layer and a second support layer stacked on the first support layer, where the first support layer is adjacent to the substrate.

In at least one implementation, the first support layer is made from a material for forming the gate insulation layer that is remained in the at least one second region after forming the gate insulation layer of the LTPS-TFT by etching, and the second support layer is made from a material for forming the gate electrode that is remained in the at least one second region after forming the gate electrode of the LTPS-TFT by etching.

In at least one implementation, a width of the support portion decreases from a first end of the support portion adjacent to the substrate to a second end away from the substrate.

In at least one implementation, an orthographic projection of each of the contact portions on the substrate has no overlap with an orthographic projection of the support portion on the substrate.

In at least one implementation, the oxide-TFT further includes a dielectric layer, where the dielectric layer covers the substrate, and a protrusion protrudes from the dielectric layer in a direction away from the substrate. The source electrode and the drain electrode are arranged on the dielectric layer and spaced apart from each other by the protrusion. The oxide semiconductor layer covers the source electrode, the drain electrode, and the dielectric layer. At least a part of the channel portion is stacked on the protrusion.

In at least one implementation, a width of the protrusion decreases from a first end of the protrusion adjacent to the substrate to a second end away from the substrate.

In at least one implementation, the oxide semiconductor layer is made from materials including indium gallium zinc oxide.

In at least one implementation, the substrate includes a base and a buffer layer disposed on the base, where the buffer layer is arranged on a side of the substrate close to the oxide semiconductor layer.

In at least one implementation, the buffer layer is made from at least one of silicon oxide or silicon nitride.

A display device is provided. The display device includes the array substrate described above.

A manufacturing method for an array substrate is provided. The manufacturing method includes the following. A substrate is provided, a low temperature poly-silicon thin film transistor (LTPS-TFT) is formed on a first region of the substrate, and a source electrode and a drain electrode of an oxide thin film transistor (oxide-TFT) are formed on a second region of the substrate. An oxide semiconductor layer covering the source electrode and the drain electrode of the oxide-TFT is formed on the second region of the substrate, where a part of the oxide semiconductor layer protrudes in a direction away from the substrate to form a convex structure. A gate insulation layer and a gate electrode of the oxide-TFT are formed on the oxide semiconductor layer sequentially, where the gate insulation layer and the gate electrode of the oxide-TFT are stacked on the convex structure. A conductive treatment is performed on ends of the oxide semiconductor layer to form contact portions, where the contact portions are respectively in contact with the source electrode and the drain electrode of the oxide-TFT, a part of the oxide semiconductor layer which is not subjected to the conductive treatment forms a channel portion, and the channel portion is at least partially formed by the convex structure.

In at least one implementation, “providing the substrate, forming the LTPS-TFT on the first region of the substrate, and forming the source electrode and the drain electrode of the oxide-TFT on the second region of the substrate” includes the following. A low temperature poly-silicon layer of the LTPS-TFT is formed on the first region of the substrate. A gate insulation layer and a gate electrode of the LTPS-TFT are formed on the low temperature poly-silicon layer sequentially and a support portion is formed on the second region of the substrate, so as to form a pre-fabricated structure. A source electrode and a drain electrode of the LTPS-TFT are formed on the low temperature poly-silicon layer, and the source electrode and the drain electrode of the oxide-TFT are formed on the second region of the substrate.

In at least one implementation, between “forming the gate insulation layer and the gate electrode of the LTPS-TFT on the low temperature poly-silicon layer sequentially and forming the support portion on the second region of the substrate, so as to form a pre-fabricated structure” and “forming the source electrode and the drain electrode of the LTPS-TFT on the low temperature poly-silicon layer, and forming the source electrode and the drain electrode of the oxide-TFT on the second region of the substrate”, “providing the substrate, forming the LTPS-TFT on the first region of the substrate, and forming the source electrode and the drain electrode of the oxide-TFT on the second region of the substrate” further includes the following. A dielectric layer is formed on the pre-fabricated structure, where the dielectric layer partially protrudes in a direction away from the substrate to form a protrusion, where the protrusion covers the support portion. “Forming the source electrode and the drain electrode of the LTPS-TFT on the low temperature poly-silicon layer, and forming the source electrode and the drain electrode of the oxide-TFT on the second region of the substrate” includes the following. The source electrode and the drain electrode of the LTPS-TFT are formed on the dielectric layer in the first region, and the source electrode and the drain electrode of the oxide-TFT are formed on the dielectric layer in the second region.

In at least one implementation, the support portion includes a first support layer and a second support layer stacked on the first support layer, where the first support layer is adjacent to the substrate, the first support layer is made from a material for forming the gate insulation layer that is remained in the second region after forming the gate insulation layer of the LTPS-TFT by etching, and the second support layer is made from a material for forming the gate electrode that is remained in the second region after forming the gate electrode of the LTPS-TFT by etching.

In at least one implementation, “providing the substrate, forming the LTPS-TFT on the first region of the substrate, and forming the source electrode and the drain electrode of the oxide-TFT on the second region of the substrate” includes the following. A low temperature poly-silicon layer of the LTPS-TFT is formed on the first region of the substrate. A pattern gate insulation layer and a pattern gate electrode of the LTPS-TFT are formed on the low temperature poly-silicon layer of the LTPS-TFT sequentially, so as to form a pre-fabricated structure. A dielectric layer is formed on the pre-fabricated structure, where the dielectric layer partially protrudes in a direction away from the substrate to form a protrusion. A source electrode and a drain electrode of the LTPS-TFT are formed on the dielectric layer in the first region, and the source electrode and the drain electrode of the oxide-TFT are formed on the dielectric layer in the second region. “Forming the oxide semiconductor layer covering the source electrode and the drain electrode of the oxide-TFT on the second region of the substrate, where the part of the oxide semiconductor layer protrudes in the direction away from the substrate to form the convex structure” further includes the following. The oxide semiconductor layer covers the protrusion and the source electrode and the drain electrode of the oxide-TFT, and the convex structure covers the protrusion.

According to the array substrate, the manufacturing method for the array substrate, and the display device that are provided herein, since the channel portion at least partially protrudes in the direction away from the substrate to form a curved structure, i.e., the overall length of the channel portion is increased without increment of the length of the oxide-TFT in the horizontal direction. In other words, by means of that the channel portion is designed to extend vertically, the length of the oxide-TFT in the horizontal direction can be reduced in a case that the length of the channel is not changed, and therefore the resolution can be improved.

### BRIEF DESCRIPTION OF THE DRAWINGS

To describe technical solutions in implementations of the disclosure more clearly, the following briefly introduces accompanying drawings required for illustrating the implementations. Apparently, the accompanying drawings in the following description illustrate some implementations. Those of ordinary skill in the art may also obtain other drawings based on these accompanying drawings without creative efforts.

FIG. 1 is a cross-sectional view of an array substrate according to implementations of the disclosure.

FIG. 2 is a flow chart illustrating a manufacturing method for an array substrate according to implementations of the disclosure.

FIG. 3 is a cross-sectional view of a structure formed via an operation at block 201 illustrated in FIG. 2.

FIG. 4 is a cross-sectional view of a structure formed via an operation at block 202 illustrated in FIG. 2.

FIG. 5 is a cross-sectional view of a structure formed via an operation at block 203 illustrated in FIG. 2.

FIG. 6 is a flow chart illustrating an operation at block 201 illustrated in FIG. 2 according to implementations.

FIG. 7 is a cross-sectional view of a structure formed via an operation at block 2011 illustrated in FIG. 6.

FIG. 8 is a cross-sectional view of a structure formed via an operation at block 2012 illustrated in FIG. 6.

FIG. 9 is a cross-sectional view of a structure formed via an operation at block 2013 illustrated in FIG. 6.

FIG. 10 is a flow chart illustrating an operation at block 201 illustrated in FIG. 2 according to other implementations.

FIG. 11 is a schematic view illustrating a display device according to implementations of the disclosure.

### DETAILED DESCRIPTION

Hereinafter, technical solutions embodied in implementations of the disclosure will be described in a clear and comprehensive manner in conjunction with the accompanying drawings. It is obvious that implementations described herein are merely some rather than all the implementations of the disclosure. All other implementations obtained by those of ordinary skill in the art based on the implementations of the disclosure without creative efforts shall fall within the protection scope of the disclosure.

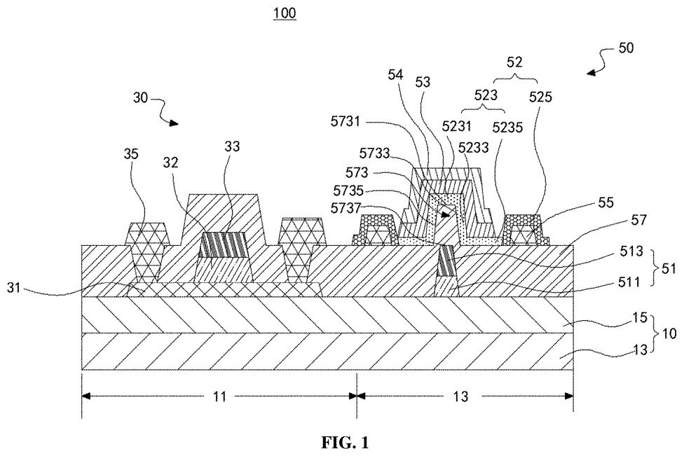

As illustrated in FIG. 1, an array substrate 100 is provided in an implementation of the disclosure. The array substrate 100 includes a substrate 10. The substrate 10 includes at least one first region 11 and at least one second region 13. A low temperature poly-silicon thin film transistor (LTPS-TFT) 30 is disposed in the first region 11, and an oxide thin film transistor (oxide-TFT) 50 is disposed in the second region 13. The oxide-TFT 50 includes an oxide semiconductor layer 52, a gate insulation layer 53, a gate electrode 54, and a source electrode and a drain electrode which are both represented by a reference numeral 55. The oxide semiconductor layer 52 includes a channel portion 523 and contact portions 525 connected to the channel portion 523. The channel portion 523, the gate insulation layer 53, and the gate electrode 54 are sequentially stacked. The source electrode 55 and the drain electrode 55 are respectively in contact with the contact portions 525. The channel portion 523 at least partially protrudes in a direction away from the substrate 10.

Since the channel portion 523 at least partially protrudes in the direction away from the substrate 10, i.e., the channel portion 523 at least partially protrudes toward the gate electrode 54, the channel portion 523 has a curved shape. The overall length of the channel portion 523 is increased without increment of a length of the oxide-TFT 50 in a horizontal direction. In other words, the length of the channel portion 523 is increased while an effective area occupied by the oxide-TFT 50 in the horizontal direction is reduced, which is beneficial to improving pixels per inch (PPI) of a display device.

The channel portion 523 includes a first part 5231 and two second parts 5233 respectively disposed at two opposite ends of the first part 5231. Each second part 5233 is bent toward the substrate 10 from one end of the first part 5231. The first part 5231 and the two second parts 5233 jointly form a protrusion relative to the substrate 10. The channel portion 5231 further includes two third parts 5235. Each third part 5235 is connected between one second part 5233 and one contact portion 525. According to implementations, the first part 5231 is substantially parallel to the substrate 10. An angle defined between each second part 5233 and the first part 5231 is larger than 90 degrees and smaller than 180 degrees. The two third parts 5235 are both parallel to the first part 5231.

In one example, the LTPS-TFT 30 includes a low temperature poly-silicon layer 31, a gate insulation layer 32, a gate electrode 33, a dielectric layer 57, and a source electrode and a drain electrode which are both represented by a reference numeral 35. The low temperature poly-silicon layer 31, the gate insulation layer 32, the gate electrode 33, and the dielectric layer 57 are sequentially stacked on the substrate 10. The source electrode 35 and the drain electrode 35 are formed on the dielectric layer 57, and the source electrode 35 and the drain electrode 35 are in contact with a non-channel region of the low temperature poly-silicon layer 31. According to implementations, the dielectric layer 57 can also be used as a buffer layer of the oxide-TFT 50.

In at least one implementation, the oxide-TFT 50 further includes a support portion 51. The support portion 51 protrudes relative to the second region 13 of the substrate 10. The channel portion 523 is at least partially disposed on the support portion 51. In at least one implementation, the support portion 51 includes a first support layer 511 and a second support layer 513 stacked on the first support layer 511. The first support layer 511 is adjacent to the substrate 10. The first support layer 511 is made from a material for forming the gate insulation layer 32 that is remained in the second region 13 when forming the gate insulation layer 32 of the LTPS-TFT 30 by etching. The second support layer 513 is made from a material for forming the gate electrode 33 that is remained in the second region 13 when forming the gate electrode 33 of the LTPS-TFT 30 by etching.

Since the support portion 51 is made from the material remained when manufacturing the gate insulation layer 32 of the LTPS-TFT 30 and the material remained when manufacturing the gate electrode 33 of the LTPS-TFT 30, the cost can be saved while the performance of the array substrate 100 is improved.

In at least one implementation, a width of the support portion 51 decreases from a first end of the support portion 51 adjacent to the substrate 10 to a second end of the support portion 51 close to the gate electrode 54 of the oxide-TFT 50. According to implementations, a cross section of the support portion 51 is substantially in the shape of a trapezoid. It is to be understood that there is no restriction on the shape of the cross section of the support portion 51. The cross section of the support portion 51 may also be in the shape of a square, a triangle, or the like.

In one example, the oxide semiconductor layer 52 is made from metal oxide semiconductor. For example, the metal oxide may include indium gallium zinc oxide (IGZO), hafnium indium zinc oxide (HIZO), indium zinc oxide (IZO), amorphous indium zinc oxide (a-InZnO), amorphous zinc oxide doped fluoride oxide (ZnO:F), indium oxide doped tin oxide (In2O3:Sn), amorphous indium oxide doped molybdenum oxide (In2O3:Mo), chromium tin oxide (Cr2SnO4), amorphous zinc oxide doped aluminum oxide (ZnO:Al), amorphous titanium oxide doped niobium oxide (TiO2:Nb), or other metal oxides. In the implementation, the metal oxide is IGZO.

Furthermore, the dielectric layer 57 is formed on the substrate 10 and the support portion 51. A protrusion 573 protrudes from the dielectric layer 57 and corresponds to the support portion 51, and the source electrode 55 and the drain electrode 55 are arranged on the dielectric layer 57 and spaced apart from each other by the protrusion 573. The protrusion 573 coves the support portion 51. In other words, the first part 5231 of the channel portion 523, the protrusion 573, and the support portion 51 are stacked together. The support portion 51 is disposed between the protrusion 573 and the substrate 10. An orthographic projection of the channel portion 523 on the substrate 10, an orthographic projection of the protrusion 573 on the substrate 10, and an orthographic projection of the support portion 51 on the substrate 10 overlap with each other.

The protrusion 573 includes a top wall 5731, a first side wall 5733, a second side wall 5735, and a bottom wall 5737. The top wall 5731 is arranged opposite to the bottom wall 5737. The top wall 5731 is connected between the first side wall 5733 and the second side wall 5735. The first part 5231 of the channel portion 523 is attached to the top wall 5731. The two second parts 5233 of the channel portion 523 are respectively attached to the first side wall 5733 and the second side wall 5735. The two third parts 5235 of the channel portion 523 are attached to the dielectric layer 57. The channel portion 523 of the oxide-TFT 50 extends across the protrusion 573.

In at least one implementation, a width of the protrusion 573 decreases from a first end of the protrusion 573 adjacent to the support portion 51 to a second end of the protrusion 573 close to the gate electrode 54 of the oxide-TFT 50.

In at least one implementation, the oxide semiconductor layer 52 is made from materials including indium gallium zinc oxide.

In at least one implementation, an orthographic projection of each contact portion 525 on the substrate 10 and an orthographic projection of the protrusion 573 on the substrate 10 do not overlap with each other.

In at least one implementation, the substrate 10 includes a base 13 and a buffer layer 15 disposed on the base 13. The support portion 51 is arranged adjacent to the buffer layer 15. The base 13 is made of glass. It can be understood that in another implementation, the base 13 can be made from other materials, such as Polyimide (PI). The buffer layer 15 can be made from at least one of silicon oxide or silicon nitride.

It can be understood that forming of the support portion 51 is not limited to that the support portion 51 is made from the material remained when manufacturing the gate insulation layer 32 of the LTPS-TFT 30 and the material remained when manufacturing the gate electrode 33 of the LTPS-TFT 30. The support portion 51 can also be made from other materials, such as silicon oxide or silicon nitride. It can be understood that the support portion 51 and the dielectric layer 57 can be omitted, as long as the channel portion 523 of the oxide semiconductor layer 52 can at least partially protrude toward the gate electrode 54 to form a curved structure. In this way, the length of the channel portion 523 can be increased without increment of the length of the oxide-TFT 50 in the horizontal direction.

In addition to the horizontal direction, the channel portion 523 can also extend in the vertical direction to increase the overall length of the channel portion 523, thereby reserving enough length for carrier diffusion. Moreover, due to the short length of the oxide-TFT in the horizontal direction, a resolution of a display panel with oxide-TFTs can be improved.

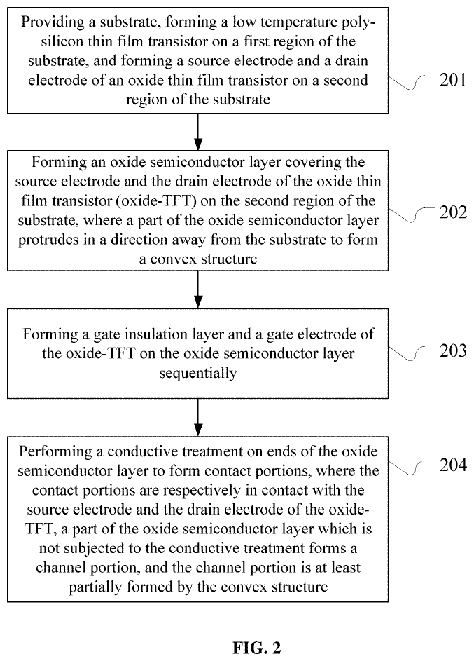

Implementations of the disclosure further provide a manufacturing method for the array substrate. As illustrated in FIG. 2, the manufacturing method begins at block 201.

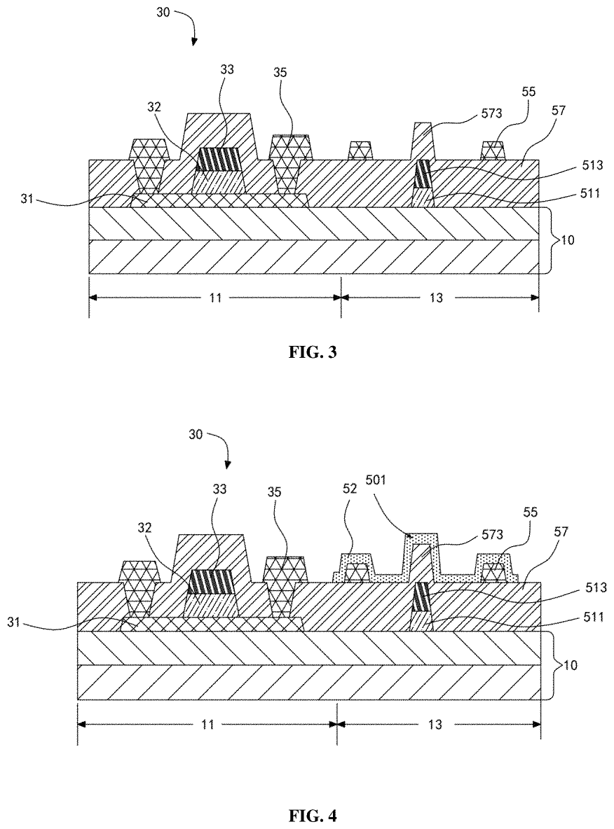

At block 201, in combination with FIG. 3, the substrate 10 is provided, the LTPS-TFT 30 is formed on the first region 11 of the substrate 10, and the source electrode 55 and the drain electrode 55 of the oxide-TFT 50 are formed on the second region 13 of the substrate 10.

At block 202, in combination with FIG. 4, an oxide semiconductor layer 52 covering the source electrode 55 and the drain electrode 55 of the oxide-TFT 50 is formed on the second region 13 of the substrate 10, where a part of the oxide semiconductor layer 52 protrudes in a direction away from the substrate 10 to form a convex structure 501.

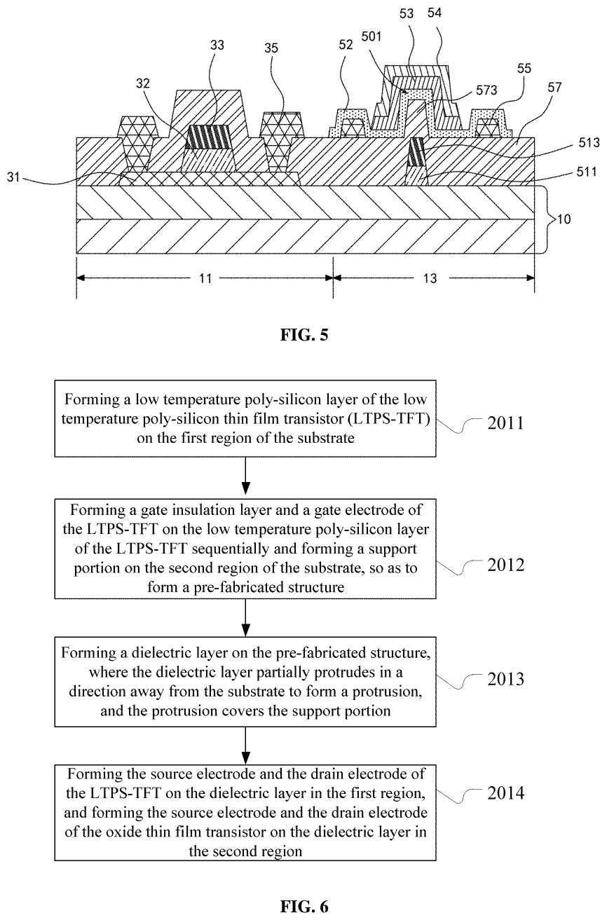

At block 203, in combination with FIG. 5, the gate insulation layer 53 and the gate electrode 54 of the oxide-TFT 50 are formed on the oxide semiconductor layer 52 sequentially, where the gate insulation layer 53 and the gate electrode 54 are stacked on the convex structure 501.

At block 204, in combination with FIG. 1, a conductive treatment is performed on ends of the oxide semiconductor layer 52 to form contact portions 525, where the contact portions 525 are respectively in contact with the source electrode 55 and the drain electrode 55 of the oxide-TFT 50, and a part of the oxide semiconductor layer 52 which is not subjected to the conductive treatment forms a channel portion 523. The channel portion 523 is at least partially formed by the convex structure 501, and the channel portion 523, the gate insulation layer 53, and the gate electrode 54 are stacked.

As illustrated in FIG. 6, the operation at block 201 includes the following.

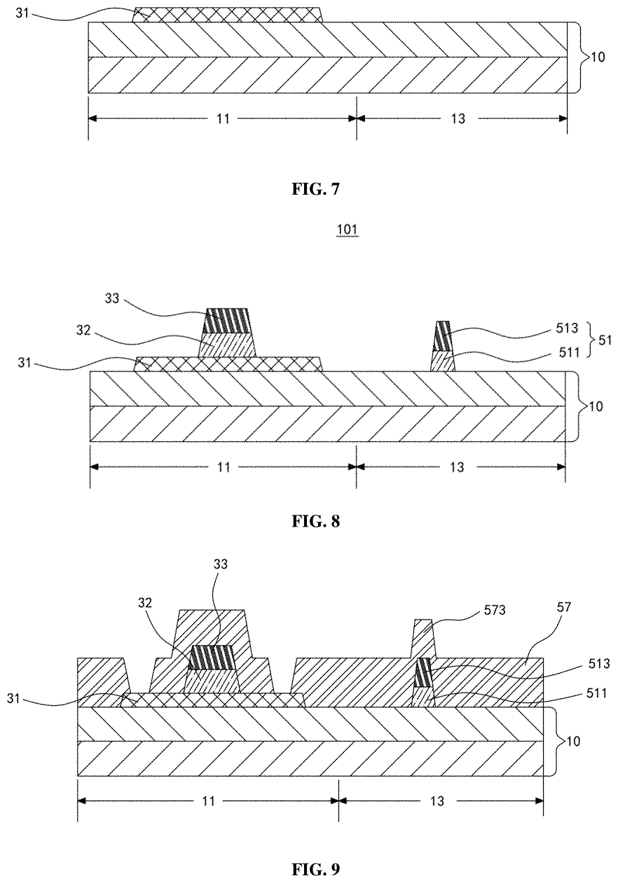

At block 2011, in combination with FIG. 7, the low temperature poly-silicon layer 31 of the LTPS-TFT 30 is formed on the first region 11 of the substrate 10.

In one example, an amorphous silicon (a-Si) film layer is formed, exposed, and etched on the substrate 10, and the patterned a-Si film layer is converted into the low temperature poly-silicon layer 31.

At block 2012, in combination with FIG. 8, the gate insulation layer 32 and the gate electrode 33 of the LTPS-TFT 31 are formed on the low temperature poly-silicon layer 31 of the LTPS-TFT 30 sequentially and the support portion 51 is formed on the second region 13 of the substrate 10, so as to form a pre-fabricated structure 101, where the support portion 51 protrudes in a direction away from the substrate 10.

The support portion 51 includes the first support layer 511 and the second support layer 513 stacked on the first support layer 511 (i.e., the first support layer 511 and the second support layer 513 are arranged in layers). The first support layer 511 is adjacent to the substrate 10. In at least one implementation, the first support layer 511 is made from a material for forming the gate insulation layer 32 that is remained in the second region 13 when forming the gate insulation layer 32 of the LTPS-TFT 30 by etching. The second support layer 513 is made from a material for forming the gate electrode 33 that is remained in the second region 13 when forming the gate electrode 33 of the LTPS-TFT 30 by etching.

At block 2013, in combination with FIG. 9, the dielectric layer 57 is formed on the pre-fabricated structure 101, where the dielectric layer 57 partially protrudes in a direction away from the substrate 10 to form the protrusion 573, and the protrusion 573 covers the support portion 51. According to implementation, the dielectric layer 57 on the second region 13 can also be used as a buffer layer of the oxide-TFT 50.

At block 2014, in combination with FIG. 3, the source electrode 35 and the drain electrode 35 of the LTPS-TFT 30 are formed on the dielectric layer 57 in the first region 11, and the source electrode 55 and the drain electrode 55 of the oxide-TFT 50 are formed on the dielectric layer 57 in the second region 13, where the source electrode 35 and the drain electrode 35 of the LTPS-TFT 30 are in contact with a non-channel region of the low temperature poly-silicon layer 31.

The operation at block 202 further includes the following. The oxide semiconductor layer 52 covers the protrusion 573, that is, the convex structure 501 covers the protrusion 573.

It can be understood that in the operation at block 2012, the support portion 51 being formed on the second region 13 of the substrate 10 can be omitted.

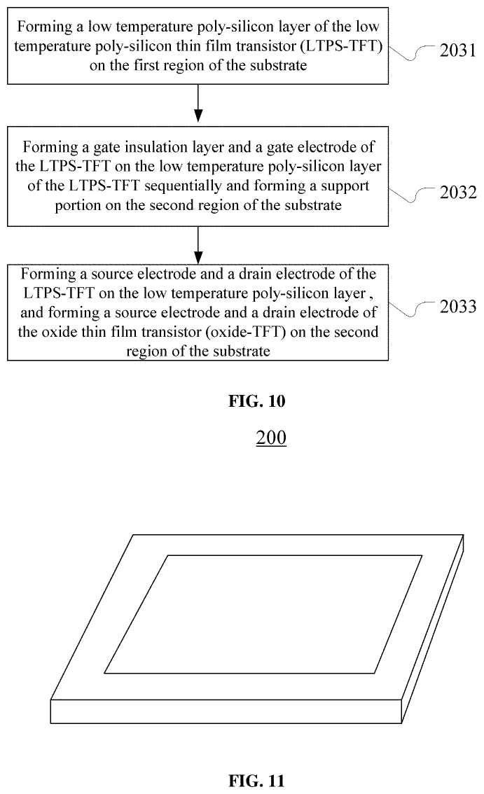

In one example, the operation at block 2013 may not be performed. That is, as illustrated in FIG. 10, the operation at block 201 includes the following.

At block 2031, the low temperature poly-silicon layer 31 of the LTPS-TFT 30 is formed on the first region 11 of the substrate 10.

At block 2032, the gate insulation layer 32 and the gate electrode 33 of the LTPS-TFT are formed on the low temperature poly-silicon layer 31 of the LTPS-TFT 30 sequentially, and the support portion 51 is formed on the second region 13 of the substrate 10.

At block 2033, the source electrode 35 and the drain electrode 35 of the LTPS-TFT 30 are formed on the low temperature poly-silicon layer 31, and the source electrode 55 and the drain electrode 55 of the oxide-TFT 50 are formed on the second region 13 of the substrate 10.

In one example, in the operation at block 202, the oxide semiconductor layer 52 covers the support portion 51.

As illustrated in FIG. 11, a display device 200 is provided. The display device 200 includes the array substrate 100 described above.

According to the array substrate 100, the manufacturing method for the array substrate 100, and the display device 200 that are provided herein, the channel portion 523 protrudes toward the gate electrode 54 to form the curved structure, that is, the overall length of the channel portion 523 is increased without increment of a length of the oxide-TFT 50 in the horizontal direction. In other words, by means of that the channel portion 523 is designed to extend vertically, the length of the oxide-TFT 50 in the horizontal direction can be reduced in a case that the length of the channel is not changed. Since the length of the channel portion 523 is increased while an effective area occupied by the oxide-TFT 50 in the horizontal direction is reduced, it is beneficial to improving the PPT of the display device 200, thereby improving the display performance of the display device 200. Furthermore, the support portion 51 is made from the material remained when manufacturing the gate insulation layer 32 of the LTPS-TFT 30 and the material remained when manufacturing the gate electrode 33 of the LTPS-TFT 30, so that the dielectric layer 57 may be stacked in a region corresponding to the support portion 51 to form a protrusion 573, thereby reducing the cost of the manufacturing.

The foregoing illustrates some implementations of the disclosure. It can be understood that for those skilled in the art, without departing from the principle of the disclosure, a number of improvements and modifications can be made, which are also regarded as the protection scope of the disclosure.

What is claimed is:

1. An array substrate, comprising:
a substrate comprising:
at least one first region; and
at least one second region, wherein a low temperature poly-silicon thin film transistor (LTPS-TFT) is disposed in the at least one first region, and an oxide thin film transistor (oxide-TFT) is disposed in the at least one second region, wherein the oxide-TFT comprises an oxide semiconductor layer, a gate insulation layer, a gate electrode, a source electrode, and a drain electrode, wherein the oxide semiconductor layer comprises a channel portion and contact portions connected to the channel portion, wherein the channel portion, the gate insulation layer, and the gate electrode are sequentially stacked; the contact portions are respectively in contact with the source electrode and the drain electrode, and the channel portion at least partially protrudes in a direction away from the substrate.

2. The array substrate of claim 1, wherein the channel portion comprises a first part and two second parts respectively disposed at two opposite ends of the first part, wherein each of the two second parts is bent toward the substrate from one of the two opposite ends of the first part.

3. The array substrate of claim 2, wherein the first part is parallel to the substrate, wherein an angle defined between each of the two second parts and the first part is larger than 90 degrees and smaller than 180 degrees.

4. The array substrate of claim 3, wherein the channel portion further comprises two third parts, wherein each of the two third parts is connected between one of the two second parts and one of the contact portions.

5. The array substrate of claim 4, wherein the two third parts are both parallel to the first part.

6. The array substrate of claim 1, wherein the oxide-TFT further comprises a support portion, wherein the support portion protrudes relative to the at least one second region of the substrate, and the channel portion is at least partially disposed on the support portion.

7. The array substrate of claim 6, wherein the support portion comprises a first support layer and a second support layer stacked on the first support layer, wherein the first support layer is adjacent to the substrate.

8. The array substrate of claim 7, wherein the first support layer is made from a material for forming the gate insulation layer that is remained in the at least one second region after forming the gate insulation layer of the LTPS-TFT by etching, and the second support layer is made from a material for forming the gate electrode that is remained in the at least one second region after forming the gate electrode of the LTPS-TFT by etching.

9. The array substrate of claim 7, wherein a width of the support portion decreases from a first end of the support portion adjacent to the substrate to a second end away from the substrate.

10. The array substrate of claim 6, wherein an orthographic projection of each of the contact portions on the substrate has no overlap with an orthographic projection of the support portion on the substrate.

11. The array substrate of claim 1, wherein
the oxide-TFT further comprises a dielectric layer, wherein the dielectric layer covers the substrate, and a protrusion protrudes from the dielectric layer in a direction away from the substrate;
the source electrode and the drain electrode are arranged on the dielectric layer and spaced apart from each other by the protrusion;
the oxide semiconductor layer covers the source electrode, the drain electrode, and the dielectric layer; and
at least a part of the channel portion is stacked on the protrusion.

12. The array substrate of claim 11, wherein a width of the protrusion decreases from a first end of the protrusion adjacent to the substrate to a second end away from the substrate.

13. The array substrate of claim 1, wherein the oxide semiconductor layer is made from materials comprising indium gallium zinc oxide.

14. The array substrate of claim 1, wherein the substrate comprises a base and a buffer layer disposed on the base, wherein the buffer layer is arranged on a side of the substrate close to the oxide semiconductor layer.

15. A display device, comprising an array substrate, the array substrate comprising:
a substrate comprising:
a first region; and
a second region, wherein a low temperature poly-silicon thin film transistor (LTPS-TFT) is disposed in the first region, and an oxide thin film transistor (oxide-TFT) is disposed in the second region, wherein the oxide-TFT comprises an oxide semiconductor layer, a gate insulation layer, a gate electrode, a source electrode, and a drain electrode, wherein the oxide semiconductor layer comprises a channel portion and contact portions connected to the channel portion, wherein the channel portion, the gate insulation layer, and the gate electrode are sequentially stacked; the contact portions are respectively in contact with the source electrode and the drain electrode, and the channel portion at least partially protrudes in a direction away from the substrate.

16. A manufacturing method for an array substrate, comprising:
providing a substrate, forming a low temperature poly-silicon thin film transistor (LTPS-TFT) on a first region of the substrate, and forming a source electrode and a drain electrode of an oxide thin film transistor (oxide-TFT) on a second region of the substrate;
forming an oxide semiconductor layer covering the source electrode and the drain electrode of the oxide-TFT on the second region of the substrate, wherein a part of the oxide semiconductor layer protrudes in a direction away from the substrate to form a convex structure;
forming a gate insulation layer and a gate electrode of the oxide-TFT on the oxide semiconductor layer sequentially, wherein the gate insulation layer and the gate electrode of the oxide-TFT are stacked on the convex structure; and
performing a conductive treatment on ends of the oxide semiconductor layer to form contact portions, wherein the contact portions are respectively in contact with the source electrode and the drain electrode of the oxide-TFT, wherein a part of the oxide semiconductor layer which is not subjected to the conductive treatment forms a channel portion, and the channel portion is at least partially formed by the convex structure.

17. The manufacturing method of claim 16, wherein “providing the substrate, forming the LTPS-TFT on the first region of the substrate, and forming the source electrode and the drain electrode of the oxide-TFT on the second region of the substrate” comprises:
forming a low temperature poly-silicon layer of the LTPS-TFT on the first region of the substrate;
forming a gate insulation layer and a gate electrode of the LTPS-TFT on the low temperature poly-silicon layer sequentially and forming a support portion on the second region of the substrate, so as to form a pre-fabricated structure; and
forming a source electrode and a drain electrode of the LTPS-TFT on the low temperature poly-silicon layer, and forming the source electrode and the drain electrode of the oxide-TFT on the second region of the substrate.

18. The manufacturing method of claim 17, wherein between “forming the gate insulation layer and the gate electrode of the LTPS-TFT on the low temperature poly-silicon layer sequentially and forming the support portion on the second region of the substrate, so as to form a pre-fabricated structure” and “forming the source electrode and the drain electrode of the LTPS-TFT on the low temperature poly-silicon layer, and forming the source electrode and the drain electrode of the oxide-TFT on the second region of the substrate”:
“providing the substrate, forming the LTPS-TFT on the first region of the substrate, and forming the source electrode and the drain electrode of the oxide-TFT on the second region of the substrate” further comprises:
forming a dielectric layer on the pre-fabricated structure, wherein the dielectric layer partially protrudes in a direction away from the substrate to form a protrusion, wherein the protrusion covers the support portion;
“forming the source electrode and the drain electrode of the LTPS-TFT on the low temperature poly-silicon layer, and forming the source electrode and the drain electrode of the oxide-TFT on the second region of the substrate” comprises:
forming the source electrode and the drain electrode of the LTPS-TFT on the dielectric layer in the first region, and forming the source electrode and the drain electrode of the oxide-TFT on the dielectric layer in the second region.

19. The manufacturing method of claim 18, wherein the support portion comprises a first support layer and a second support layer stacked on the first support layer, wherein the first support layer is adjacent to the substrate, the first support layer is made from a material for forming the gate insulation layer that is remained in the second region after forming the gate insulation layer of the LTPS-TFT by etching, and the second support layer is made from a material for forming the gate electrode that is remained in the second region after forming the gate electrode of the LTPS-TFT by etching.

20. The manufacturing method of claim 16, wherein “providing the substrate, forming the LTPS-TFT on the first region of the substrate, and forming the source electrode and the drain electrode of the oxide-TFT on the second region of the substrate” comprises:
forming a low temperature poly-silicon layer of the LTPS-TFT on the first region of the substrate;
forming a gate insulation layer and a gate electrode of the LTPS-TFT on the low temperature poly-silicon layer of the LTPS-TFT sequentially, so as to form a pre-fabricated structure;
forming a dielectric layer on the pre-fabricated structure, wherein the dielectric layer partially protrudes in a direction away from the substrate to form a protrusion; and
forming a source electrode and a drain electrode of the LTPS-TFT on the dielectric layer in the first region, and forming the source electrode and the drain electrode of the oxide-TFT on the dielectric layer in the second region;
“forming the oxide semiconductor layer covering the source electrode and the drain electrode of the oxide-TFT on the second region of the substrate, wherein the part of the oxide semiconductor layer protrudes in the direction away from the substrate to form the convex structure” further comprises:
the oxide semiconductor layer covering the protrusion and the source electrode and the drain electrode of the oxide-TFT, and the convex structure covering the protrusion.
